(19) United States
(12) Patent Application Publication
(10) Pub. No.: US 2005/0233571 A1
(43) Pub. Date: Oct. 20, 2005

(54) Flip chip package, semiconductor package with bumps and method for manufacturing semiconductor package with bumps

(75) Inventors: Su Tao, Kaohsiung (TW); Min-Lung Huang, Kaohsiung (TW); Ho-Ming Tong, Taipei (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaoshiung (TW)

(21) Appl. No.: 10/921,967

(22) Filed: Aug. 20, 2004

(30) Foreign Application Priority Data
Aug. 22, 2003 (TW) 092123210

(51) Int. Cl. H01L 21/44; H01L 21/48

(52) U.S. Cl. 438/614; 438/613; 438/612; 438/108

(57) ABSTRACT

A semiconductor chip with bumps formed therein comprises an active surface, a plurality of bonding pads, a passivation layer, a plurality of first UBMs (under bump metallurgy), a second UBM, a plurality of first bumps, and a plurality of second bumps. The bonding pads are disposed on the active surface of the semiconductor chip. The passivation layer covers the active surface of the semiconductor chip with the pads exposed out of the passivation layer. The first UMBs are individually disposed on the bonding pads. The second UMB is disposed on at least two of the bonding pads. The first bumps are disposed on the first UMBs. The second bumps are disposed on the second UBM.

### BACKGROUND OF THE INVENTION

1. Field of Invention

This invention relates to a flip chip package. More particularly, the present invention is related to a flip chip package with solder bars formed therein.

2. Related Art

A well-known semiconductor package, such as a flip chip package is applicable to communication products, portable electronics products, and packages for high-frequency chips. Referring to FIG. 1, it discloses a conventional and well-know flip chip package 10, which mainly comprises a chip 20 attached to a substrate 30 in a flip-chip bonding type. The chip 20 has an active surface 22 and a plurality of bonding pads 24 formed thereon. Besides, a plurality of bumps 26 electrically and mechanically connected to the contacts 32 of the substrate 30. The bumps 26 are formed by conventional bumping process and C4 technology (Controlled Collapse Chip Connection). Furthermore, an underfill 28 is disposed between the chip 20 and the substrate 30 and encapsulates the bumps 26. In this arrangement, the bonding pads 24 are utilized for signal transmitting, grounded to the substrate and to be noted that the bonding pads 24 are connected to the bumps 26 separately and substantially have the same size with each other.

As mentioned above, the voltage regulator is provided as a DC to DC converter so as to provide the electronics system with a stable power supply. In apparatus with low power, such as notebooks, mobile phones, usually there is needed an efficient switch converter to manage power supply. However, a well-know and conventional switch converter is manufacture by the packages of small outline IC, small outline package and such packages usually have larger parasitic inductance and parasitic resistance. In addition, such packages can not dissipate the heat, arisen out of electronics systems with high power and high frequency devices formed therein, to external devices or the outside more quickly.

Although the U.S. Pat. No. 6,229,220 and the TW. Pat 517370 disclose the method of keeping the bump height and the distance between the substrate and the chip from being collapsed by utilizing bumps with two different solder materials formed therein. However, such package still not provides a package with a better thermal and electrical performance.

Therefore, providing another flip chip package to solve the mentioned-above disadvantages is the most important task in this invention.

### SUMMARY OF THE INVENTION

In view of the above-mentioned problems, this invention is to provide a flip chip package having an electrically conductive bar formed therein for enhancing the thermal and electrical performance.

To achieve these and other advantages and in accordance with the purpose of the invention, as embodied and broadly described herein, the invention specifically provides a flip chip package applicable to such high thermal and electrical performance. Therein, the flip chip package mainly comprises a chip, which has an active surface, a plurality of bonding pads, a passivation layer formed on the active surface and leaves the bonding pads exposed, a plurality of first under bump metallurgy layers, a second under bump metallurgy layer, a plurality of first bumps formed on the first under bump metallurgy layers and a second bump formed on the second under bump metallurgy layer. To be noted that the second under bump metallurgy layer is disposed on at least two of the bonding pads and a portion of the passivation layer between said two bonding pads and each said first under bump metallurgy layer is disposed on one of the corresponding bonding pads respectively. Namely, the second under bump metallurgy layer is extended from one bonding to another boning pad and located over the passivation layer located between the two bonding pads. In other words, the area of said each first under bump metallurgy layer is smaller than that of the second under bump metallurgy layer from a top view. Moreover, the second bump disposed on the second under bump metallurgy layer may form a bar, a ring, a rectangle and an ellipse. When the material of the second bump is made of solder, it becomes a solder bar.

As mentioned above, the second under bump metallurgy layer has a large area and the second bump has a large size so that the second bump can be taken as ground bump to ground to a substrate. Hence, the electrical and thermal performance will increase and enhance.

It is to be understood that both the foregoing general description and the following detailed description are exemplary, and are intended to provide further explanation of the invention as claimed.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of a conventional flip chip package;

FIG. 2 is a top view of a flip chip package according to the preferred embodiment of the present invention;

FIG. 3 is a cross-sectional view of a flip chip package of FIG. 2;

FIG. 4 is a bottom view of a flip chip package of FIG. 2;

FIG. 5a and FIG. 5b are cross-sectional views of solder bump and solder bar provided in the flip chip package of FIG. 2; and

FIGS. 6 to 11 are partially enlarged cross-sectional views showing the progression of steps for forming the flip chip package according to the preferred embodiment of this invention.

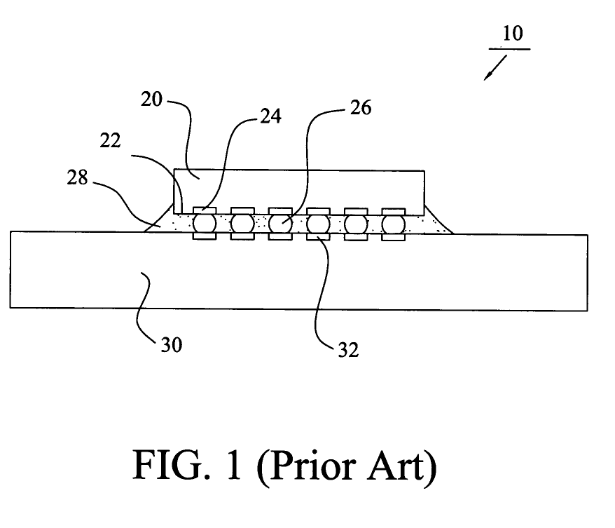

### DETAILED DESCRIPTION OF THE INVENTION

The flip chip package according to the preferred embodiments of this invention will be described herein below with reference to the accompanying drawings, wherein the same reference numbers are used in the drawings and the description to refer to the same or like parts.

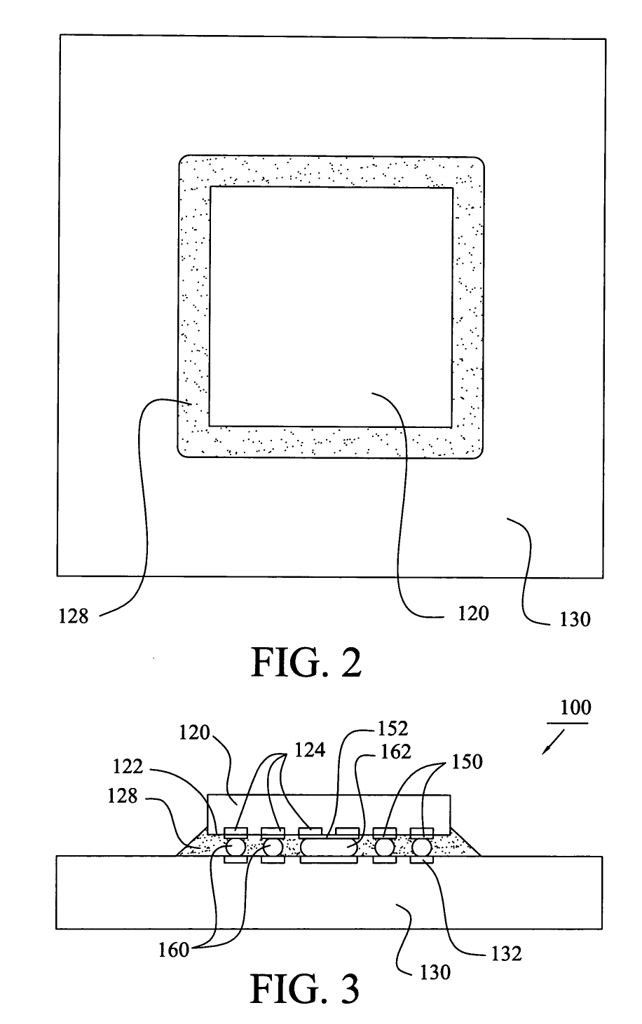

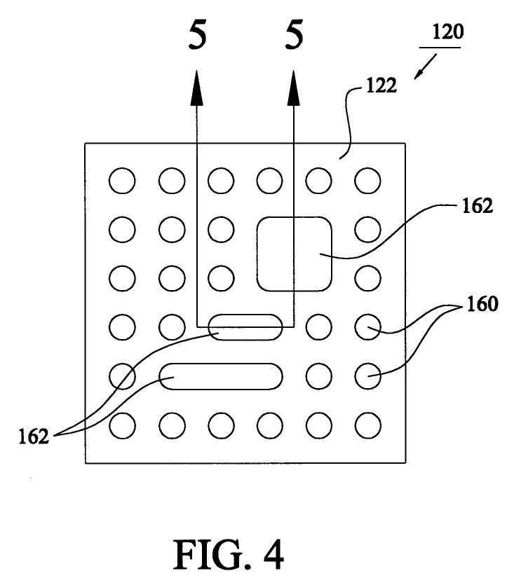

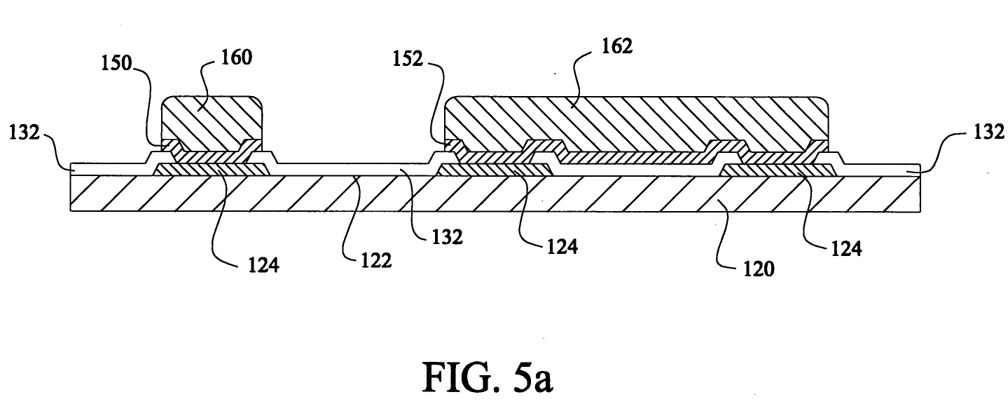

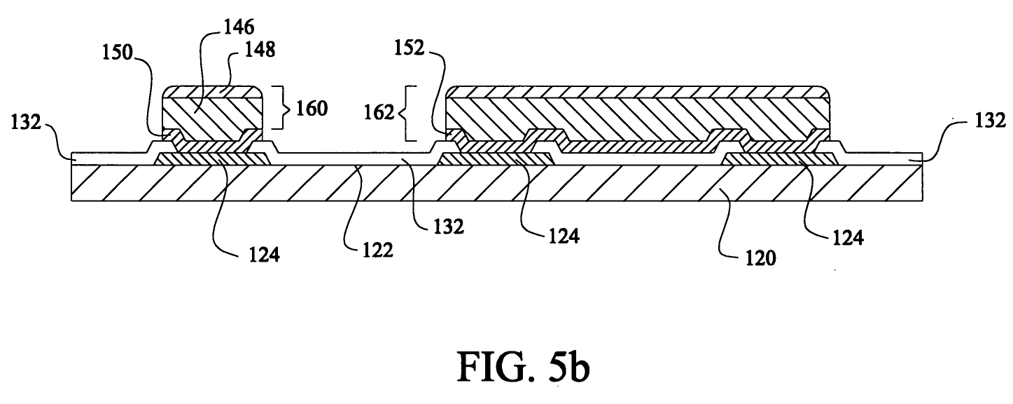

As shown in FIGS. 2, 3 and 4, which illustrate a preferred embodiment of this invention. The flip chip package 100 mainly comprises a chip 120 flip-chip bonded to a substrate 130. Said chip 120 has an active surface 122 and a plurality of bonding pads 124 formed on the active surface 122. A plurality of bumps, including the solder bump 160 and the solder bar 162 as shown in FIGS. 3 and 4, are disposed over the bonding pads 124. A plurality of under bump metallurgy layers 150 and 152 formed between the bumps and the chip 120. To be more clearly, the under bump metallurgy layer 150 is substantially shaped into a circle and connected to the solder bump 160. In addition, the under bump metallurgy layer 152 covers at least two bonding pads 124 by extending one of the two bonding pads 124 to the other of the two bonding pads 124. Usually, there is a passivation layer 132, as shown in FIG. 5a, formed over the active surface 122 and leaves the bonding pads 124 exposed. Accordingly, as mentioned above and the under bump metallurgy layer 152 may extend along the passivation layer 123 between the two bonding pads 124 as shown in FIG. 5a. On the basis, the bumps, such as the solder bar 162 is disposed over the two boning pads 124 and a portion of the passivation layer 132 between the two bonding pads 124.

As mentioned above, the chip 120 are electrically and mechanically connected to the substrate 130 through the under bump metallurgy layers 150 and 152, and the bumps 160 and 162. Moreover, in order to release the stress at the bumps 160 and 162, there is further provided an underfill 128 disposed between the chip 120 and the substrate 130 for being utilized for releasing the stress to prevent the bumps 160 and 162 from being damaged.

To be noted that the bonding pads 124 of the chip 120 can be transmitted the signals from the chip 120, and grounded to the substrate 130 through the solder bar 162 so as to enhance the electrical and thermal performance. Because the under bump metallurgy layer 152 covering at least two bonding pads 124, the area of the under bump metallurgy layer 152 is usually grounded to the substrate 130 or regarded as a power terminal for enhancing the electrical and thermal performance of the package. To be noted, as shown in FIG. 4, the solder bar 162 may be shaped into a rectangle with a curved edge, an ellipse, a ring and the solder bump 160 may be shaped into a circle. Namely, the first under bump metallurgy layer may be shaped into a circle; and the second under bump metallurgy layer may be shaped into a rectangle with a curved edge, an ellipse, a ring.

Next, referring to FIG. 5a again, it illustrates a chip 120 not attached to the substrate 130. Usually, when the bumps are solder bumps 160 and a solder bar 162, the bumps are eutectic bumps with a ratio of lead to tin being 37 to 63. When the bumps 160 and 162 are high-lead bumps, the ratio of the bumps 160 and 162 of tin to lead is 5 and 95. In addition, the bumps 160 and 162 usually comprise anther metals formed therein, such as In.

Moreover, referring to FIG. 5b, it illustrates another embodiment showing the chip 120 is not attached to the substrate 130. Specifically, the difference of this embodiment from that as shown above, the solder bumps 160 and the solder bar 162 both has a first solder material and a second solder material, with a high melting point than that of the first solder material, formed on the first solder material respectively so as to keep the solder bumps 160 and the solder bar 162 from being collapsed after the solder bumps 160 and the solder bar 162 are reflowed. Optionally, the melting point of the first solder material is higher than the second solder material at about 20° C. For example, the first solder material 146 has a solder composition with a ratio of tin to lead being 5 to 95 and the second solder material has a solder composition with a ratio of tin to lead being 63 to 37. Therein, the melting point of the second solder material is ranged between 200 and 250° C.; and the melting point of the first solder material is ranged between 320 and 360° C. On the basis, when the bumps are reflowed, the second solder material is reflowed to encapsulate the first solder material and have the first solder material secured to the second solder material.

Moreover, the contacts on the substrate may have the same shape with that of the corresponding under bump metallurgy layers so as to have the bumps secured to the substrate well. In addition, the solder bar 162 has a larger size and area than that of the solder bump 160 so that the electrical performance and the thermal performance of the package 100 can be enhanced.

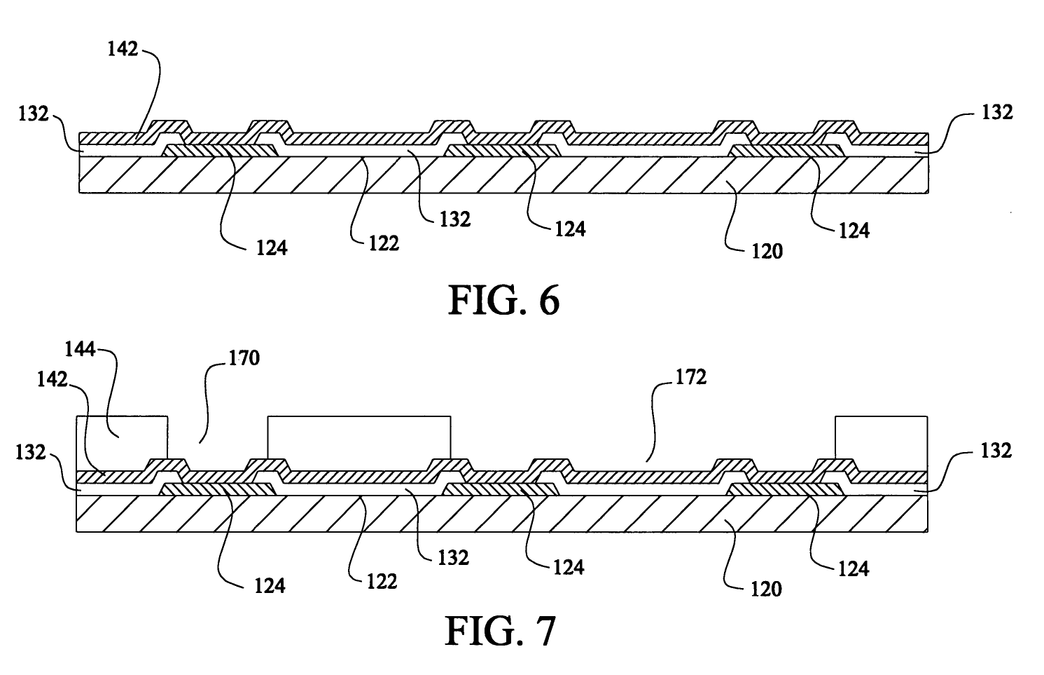

Next, referring to FIGS. 6 to 12, which illustrate the manufacture processes of the flip chip package as shown above. Again, referring to FIG. 6, the chip 120 has an active surface 122 and a plurality of bonding pads 124 formed thereon. Therein, a passivation layer 123 is disposed on the active surface 122 and leaves the bonding pads 124 exposed. Then, a metal layer 142, usually called an under bump metallurgy layer, is formed over the active surface and the passivation layer. Therein, the metal layer 142 has three layers formed therein. An adhesion layer, an oxidation barrier and a wetting layer are formed from the side close to the active surface 122 to the other side far away from the active surface 122.

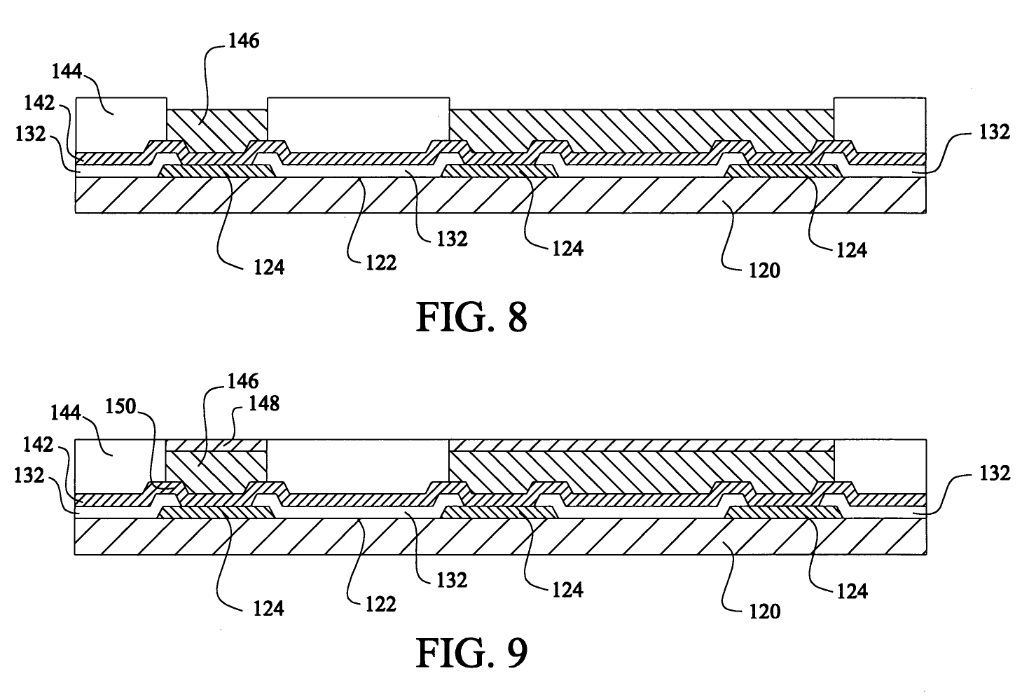

Next, referring to FIG. 7, a photo-resist layer 144 is formed and then a plurality of openings 170 and 172 formed in the photoresist layer 144 by lithography and development. Afterwards, as shown in FIG. 8, a first solder material is disposed in the openings 170 and 172. Next, a second solder material 148 with a melting point lower than that of the first solder material 146 is disposed on the first solder material 146. Therein, the first solder material 146 and the second solder material 148 can be formed by electroplating or screen-printing methods.

Then, optionally, a reflow process is performed to have the first solder material 146 securely attached to the second solder material 148 and the first solder material 146 is secured to the chip 120, when the first solder material 146 and the second solder material 148 is formed by screen-printing.

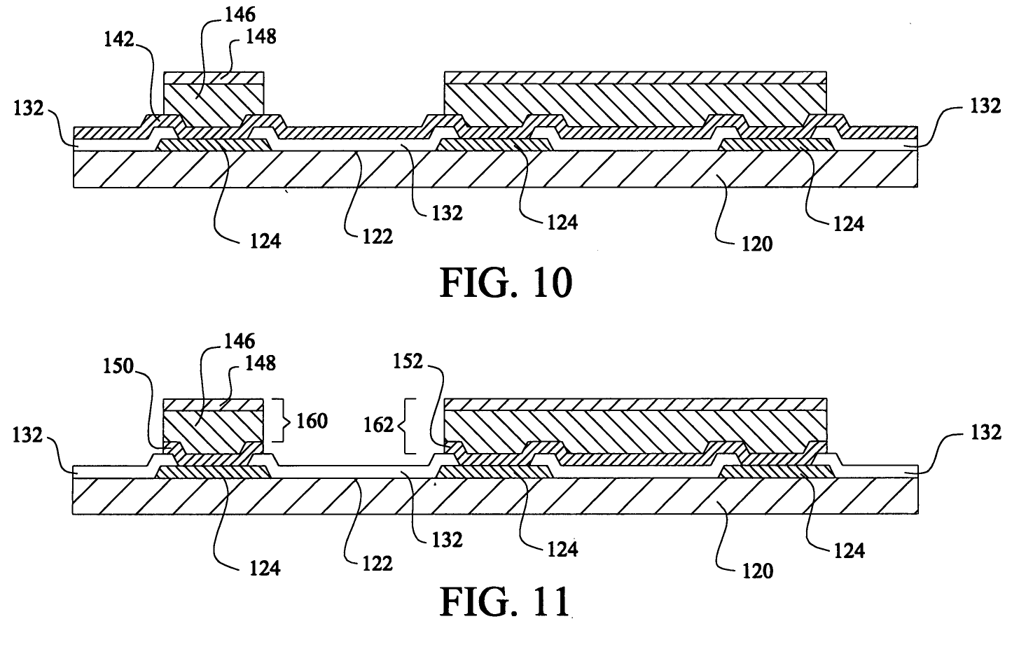

Next, as shown in FIG. 10, the photo-resist layer 144 is then removed. Then, an etching process is performed to pattern the under bump metallurgy. Therein, the portion of the under bump metallurgy layer is not covered by the first solder material is removed. To be noted, if a reflow process is not performed to have the first solder material 146 and the second solder material 148 secured to each other, such reflow process can be performed after the patterned under bump metallurgy layer is formed.

As mentioned above, if only one solder material is formed in the openings 170 and 172, the photo-resist layer 144 can be removed in sequence of the step of forming solder material in the openings 170 and 172.

Although the invention has been described in considerable detail with reference to certain preferred embodiments, it will be appreciated and understood that various changes and modifications may be made without departing from the spirit and scope of the invention as defined in the appended claims.

1. A flip chip package, comprising:
a chip having an active surface and a passivation layer formed on the active surface, wherein a plurality of bonding pads are formed on the active surface and the passivation layer leaves the bonding pads exposed;
a plurality of first under bump metallurgy layers formed on the bonding pads respectively;
a second under bump metallurgy layer formed on two of the bonding pads and extended from one of said two bonding pads to the other of said two bonding pads;
a plurality of bumps formed on the first under bump metallurgy layers and the second under bump metallurgy layer; and
a substrate having a plurality of bump pads, the bump pads electrically connected to the bumps.

2. The flip chip package of claim 1, further comprising solder pastes, wherein each solder paste is provided between the bump pad and the bump.

3. The flip chip package of claim 2, wherein the melting point of the bump is higher than that of the solder paste.

4. The flip chip package of claim 2, wherein the melting point of the bump is higher than that of the solder paste at about 20° C.

5. The flip chip package of claim 2, wherein the bump is a high-lead solder bump.

6. The flip chip package of claim 2, wherein the solder paste is a eutectic solder.

7. The flip chip package of claim 1, wherein the second under bump metallurgy layer covers a portion of the passivation layer.

8. The flip chip package of claim 1, further comprising an underfill disposed between the substrate and the chip.

9. The semiconductor package of claim 1, wherein the bump on the second under bump metallurgy is grounded to the substrate.

10. A semiconductor package with bumps formed therein, comprising:
a chip, having an active surface and a-passivation layer formed on the active surface, wherein a plurality of first bonding pads and second bonding pads are formed on the active surface and the passivation layer leaves the first and the second bonding pads exposed;
a plurality of first under bump metallurgy layers formed on the first bonding pads respectively;
a second under bump metallurgy layer formed on the second bonding pads and a portion of the passivation layer between the second bonding pads; and
a plurality of bumps formed on the first under bump metallurgy layers and the second under bump metallurgy layer, and located over the portion of the passivation layer.

11. The semiconductor package of claim 10, wherein the area of each of the first under bump metallurgy layer is smaller than the area of the second under bump metallurgy layer.

12. The semiconductor package of claim 10, wherein the first under bump metallurgy is shaped into a circle.

13. The semiconductor package of claim 10, wherein the second under bump metallurgy is shaped into a ring from a top view.

14. The semiconductor package of claim 10, wherein the second under bump metallurgy is shaped into a rectangle with a curved edge from a top view.

15. The semiconductor package of claim 10, wherein the second under bump metallurgy is shaped into an octagon from a top view.

16. The semiconductor package of claim 10, wherein the second under bump metallurgy is shaped into an ellipse from a top view.

17. The semiconductor package of claim 10, wherein the bump formed on the second under bump metallurgy is a solder bar.

18. The semiconductor package of claim 10, further comprising a solder paste formed on the bump.

19. The semiconductor package of claim 10, wherein the bumps are copper bumps.

20. A method for manufacturing a semiconductor package, comprising:
providing a chip, the chip having an active surface and a passivation layer formed on the active surface, wherein first bonding pads and two second bonding pads are formed on the active surface and the passivation layer leaves the first and the second bonding pads exposed;
froming a metal layer over the first bonding pads, the second bonding pads and the passivation layer;
disposing a photo-resist layer on the passivation layer so as to form a plurality of first openings exposing a first portion of the metal layer located on the first bonding pads respectively and a second opening exposing a second portion of the metal layer located on two of the second bonding pads and a portion of the passivation layer therebetween;
forming a plurality of first bumps in the first openings and a second bump in the second opening;
removing the photo-resist layer; and
removing the portion of the metal layer not covered by the first bumps and the second bump to form a first under bump metallurgy layers and a second under bump metallurgy layer, wherein the first bumps are disposed on the first under bump metallurgy layers respectively and the second bump is disposed on the second under bump metallurgy layer.

21. The method of claim 20, further comprising a step of forming solder pastes on the first bumps and the second bumps respectively.

22. The method of claim 20, further comprising a step of performing a reflow process to have the first bumps and the second bump securely attached to the first under bump metallurgy layers and the second under bump metallurgy layer.
